(19) United States
(12) Patent Application Publication
(10) Pub. No.: US 2025/0337422 A1
(43) Pub. Date: Oct. 30, 2025

(54) COMPLEMENTARY CURRENT-STEERING DIGITAL-TO-ANALOG CONVERTER

(71) Applicant: MEDIATEK INC., Hsinchu City (TW)

(72) Inventors: Chih-Hou TSAI, Hsinchu City (TW); Chien-Yuan CHENG, Hsinchu City (TW); Ting-Yu KO, Hsinchu City (TW); Shu-Lin CHANG, Hsinchu City (TW)

(21) Appl. No.: 19/260,802

(22) Filed: Jul. 7, 2025

Related U.S. Application Data
(63) Continuation-in-part of application No. 18/325,035, filed on May 29, 2023, now Pat. No. 12,355,467.
(60) Provisional application No. 63/370,398, filed on Aug. 4, 2022.

(51) Int. Cl. H03M 1/06

(52) U.S. Cl. CPC H03M 1/0604

(57) ABSTRACT

A complementary current-steering digital-to-analog converter (DAC) including a p-type DAC as well as an n-type DAC is shown. The p-type DAC has p-type current sources, and the n-type DAC has n-type current sources. The p-type current sources are coupled to a first input terminal or a second input terminal of a transimpedance amplifier (TIA) according to a digital input of the complementary current-steering DAC. The n-type current sources are coupled to the first input terminal or the second input terminal of the TIA according to the digital input of the complementary current-steering digital-to-analog converter.

### CROSS REFERENCE TO RELATED APPLICATIONS

This application is a Continuation-In-Part of application Ser. No. 18/325,035, filed May 29, 2023, which claims the benefit of provisional Application No. 63/370,398, filed Aug. 4, 2022, the entirety of which is incorporated by reference herein.

### BACKGROUND OF THE INVENTION

### Field of the Invention

The present invention relates to digital-to-analog converters (DACs), and, in particular, it relates to a current-steering DAC.

### Description of the Related Art

Technological progress (e.g., from WiFi 5 to WiFi 8) has resulted in an increase in the requirements for error vector magnitude (EVM), as well as making radio frequency (RF) impediments more obvious. This means that digital calibration is even more necessary that before. There is a trade-off between the DAC set point and DAC noise.

A low-noise DAC with a small circuit size and good high-power performance is called for.

### BRIEF SUMMARY OF THE INVENTION

A complementary current-steering digital-to-analog converter (DAC) is introduced.

A complementary current-steering digital-to-analog converter in accordance with an exemplary embodiment of the disclosure includes a transimpedance amplifier (TIA), a p-type digital-to-analog converter (PDAC), and an n-type digital-to-analog converter (NDAC). The PDAC has a plurality of p-type current sources, wherein the p-type current sources are coupled to a first input terminal or a second input terminal of the TIA according to a digital input of the complementary current-steering DAC. The n-type DAC has a plurality of n-type current sources, wherein the n-type current sources are coupled to the first input terminal or the second input terminal of the TIA according to the digital input of the complementary current-steering DAC. With the flexibility of the bias current coupled to the TIA, the fewer current sources are required and the circuit size is considerably reduced.

In an exemplary embodiment, the complementary current-steering DAC has a binary weighted circuit, which is configured to sink or output an adjustment current from or to the second input terminal of the TIA. Or, the binary weighted circuit is configured to sink or output an adjustment current from or to the first input terminal of the TIA.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates a complementary current-steering digital-to-analog converter (DAC) 100 in accordance with an exemplary embodiment of the present invention;

FIGS. 2A to 2H show how a 3-bit DAC 200 works in accordance with an exemplary embodiment of the present invention;

FIG. 3 shows an N-bit DAC 300 in accordance with an exemplary embodiment of the present invention;

FIGS. 4A˜4H show how a 3-bit DAC 400 works in accordance with another exemplary embodiment of the present invention;

FIG. 5 shows an N-bit DAC in accordance with an exemplary embodiment of the present invention.

### DETAILED DESCRIPTION OF THE INVENTION

The following description enumerates various embodiments of the disclosure, but is not intended to be limited thereto. The actual scope of the disclosure should be defined according to the claims. The various blocks may be implemented by special circuits. The circuit components may be directly connected to each other without additional components as the circuit illustrated in the figures. Or, there may be some additional components coupled between the illustrated circuit components.

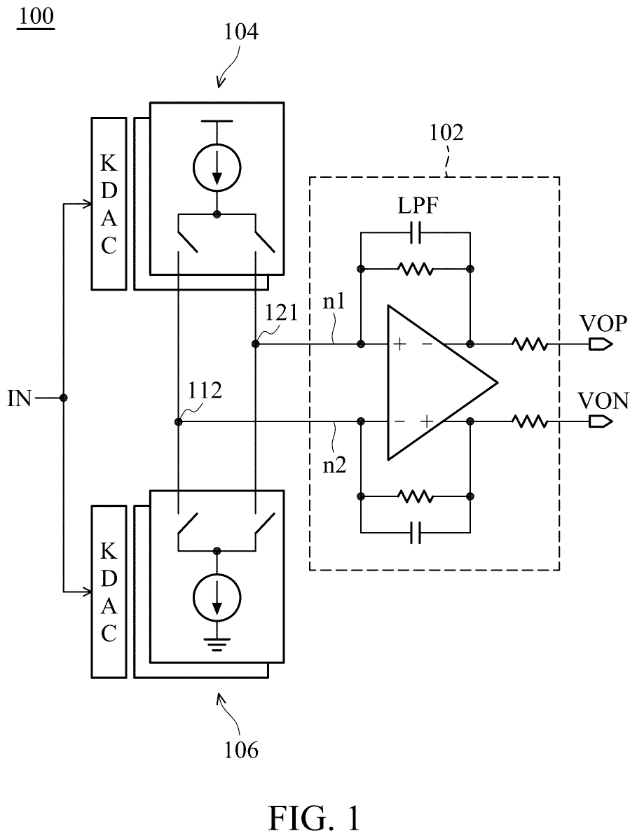

FIG. 1 illustrates a complementary current-steering digital-to-analog converter (DAC) 100 in accordance with an exemplary embodiment of the present invention. The complementary current-steering DAC 100 has a transimpedance amplifier (abbreviated as TIA) 102, a p-type digital-to-analog converter (abbreviated as PDAC) 104, and an n-type digital-to-analog converter (abbreviated as NDAC) 106. The TIA 102 may be known as a low-pass filter.

The PDAC 104 has a plurality of p-type current sources (e.g., implemented by PMOSs). The p-type current sources are coupled to a first input terminal n1 or a second input terminal n2 of the TIA 102 according to the digital input IN of the complementary current-steering DAC 100.

The NDAC 106 has a plurality of n-type current sources (e.g., implemented by NMOSs). The n-type current sources are coupled to the first input terminal n1 or the second input terminal n2 of the TIA 102 according to the digital input IN of the complementary current-steering DAC 100.

After the current-steering digital-to-analog conversion, an analog output is represented by the difference between VOP and VON.

Different from a conventional current-steering DAC whose TIA has a first input terminal (n1) constantly connected to a n-type current source and a second input terminal (n2) constantly connected to another n-type current source, the NDAC 106 form the complementary current-steering structure with the PDAC 104. With the flexibility of the bias current coupled to the TIA, the fewer current sources are required and the circuit size is considerably reduced.

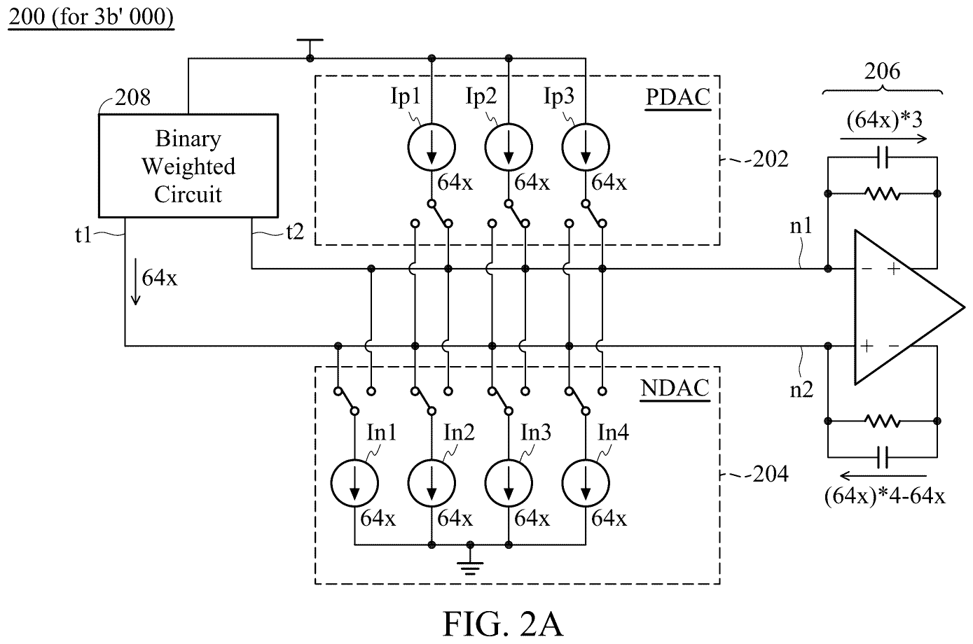

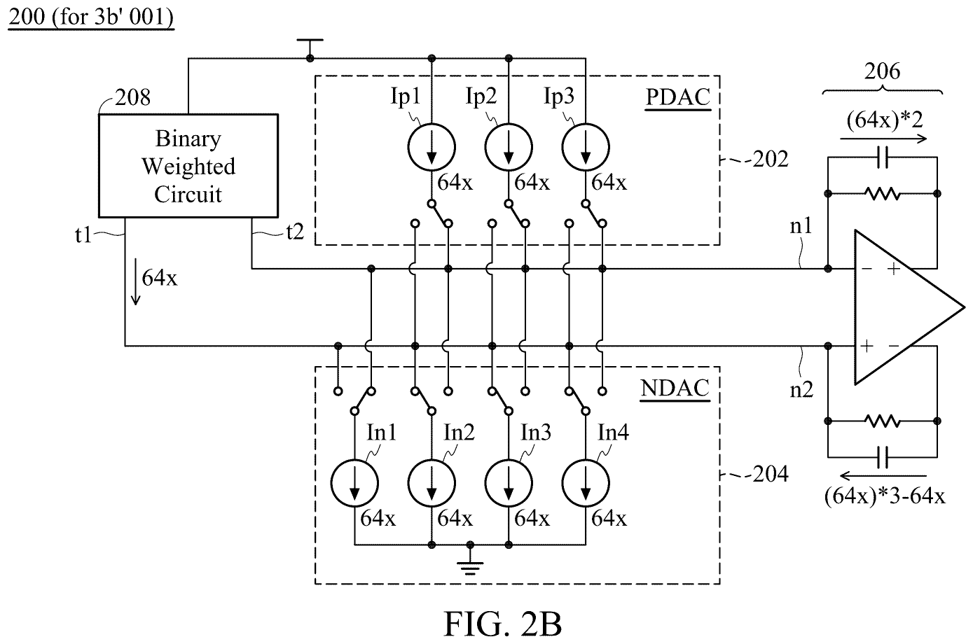

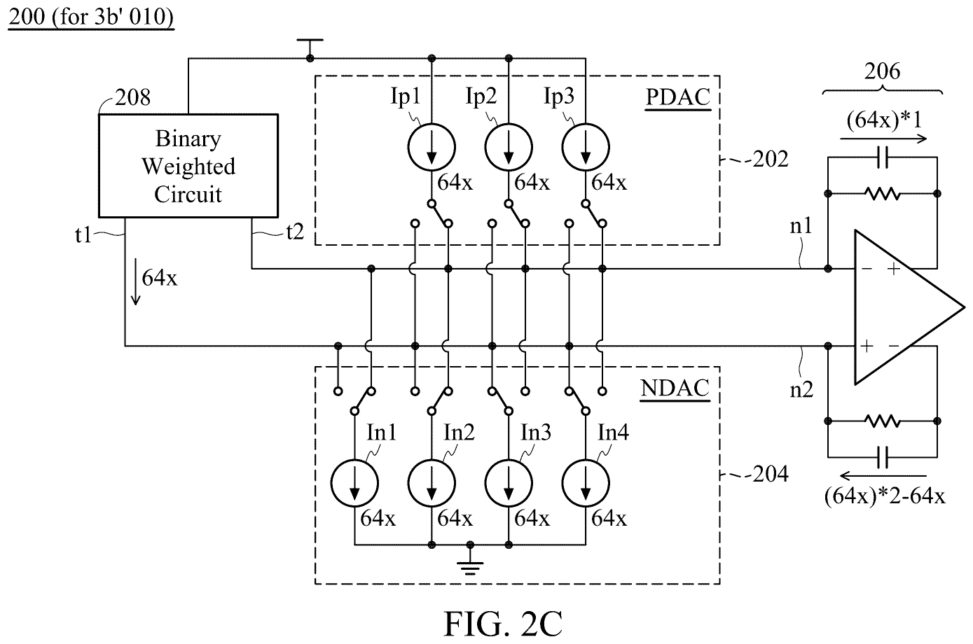

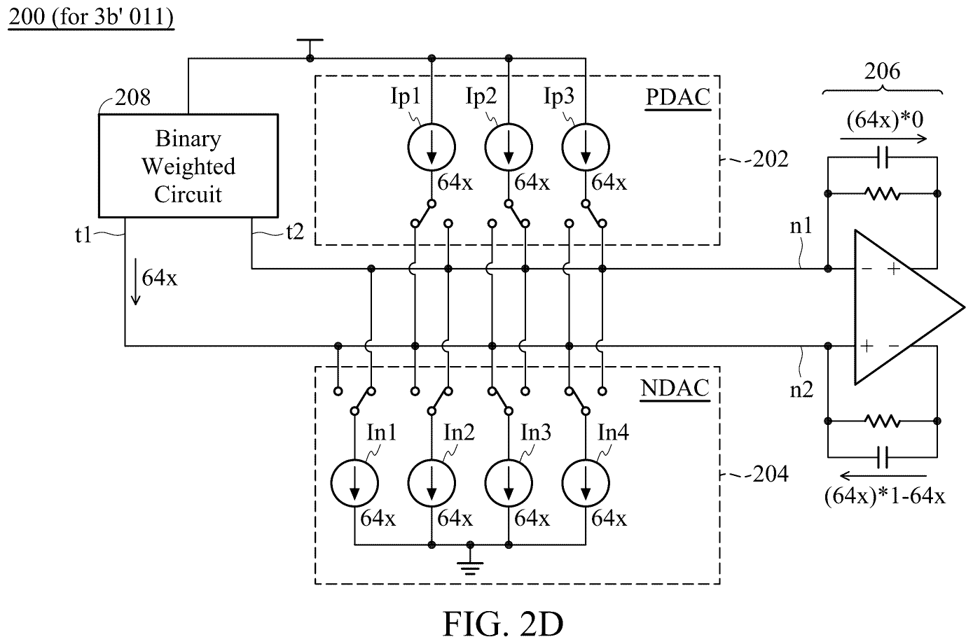

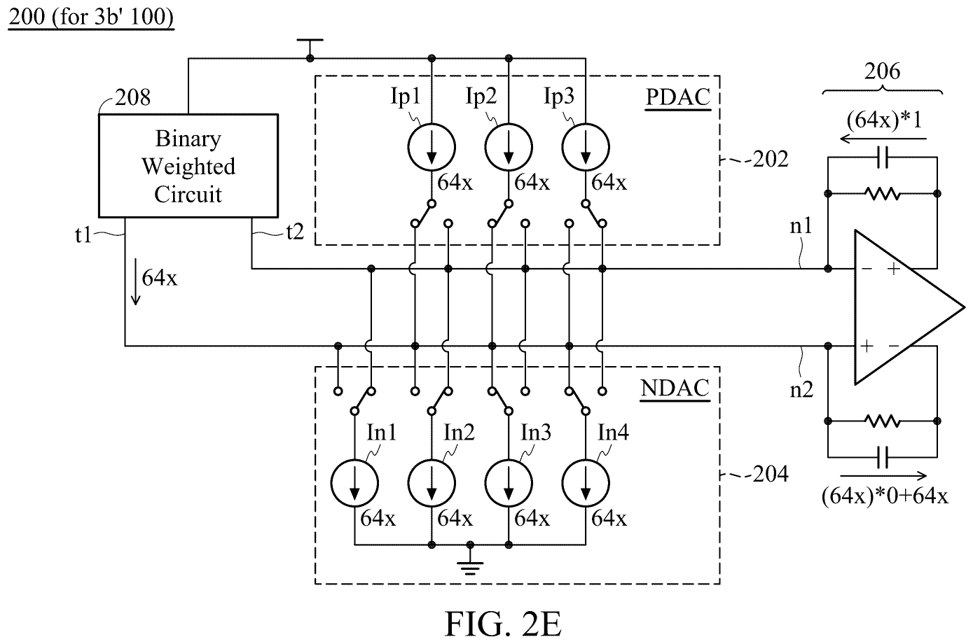

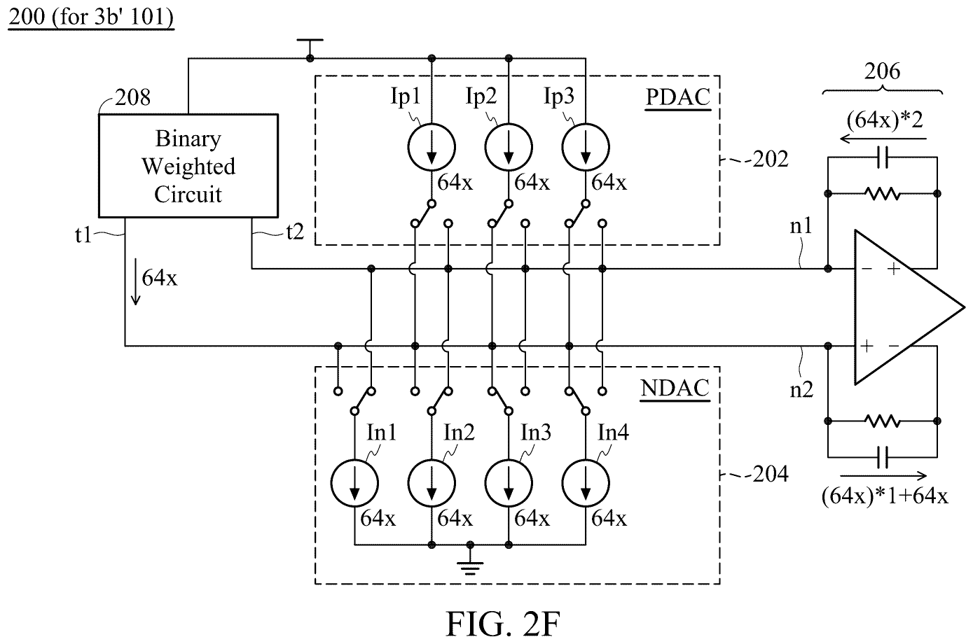

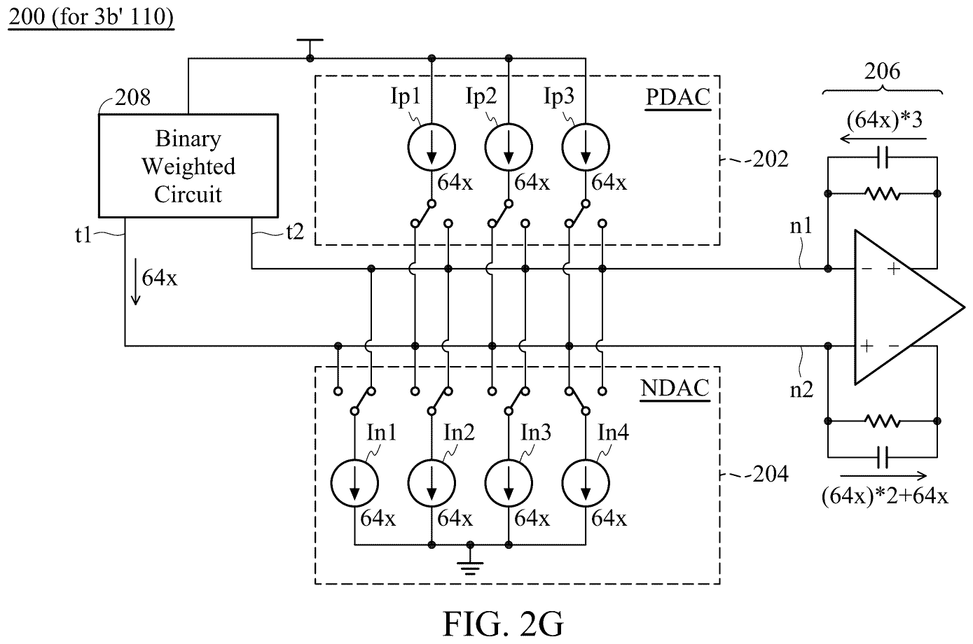

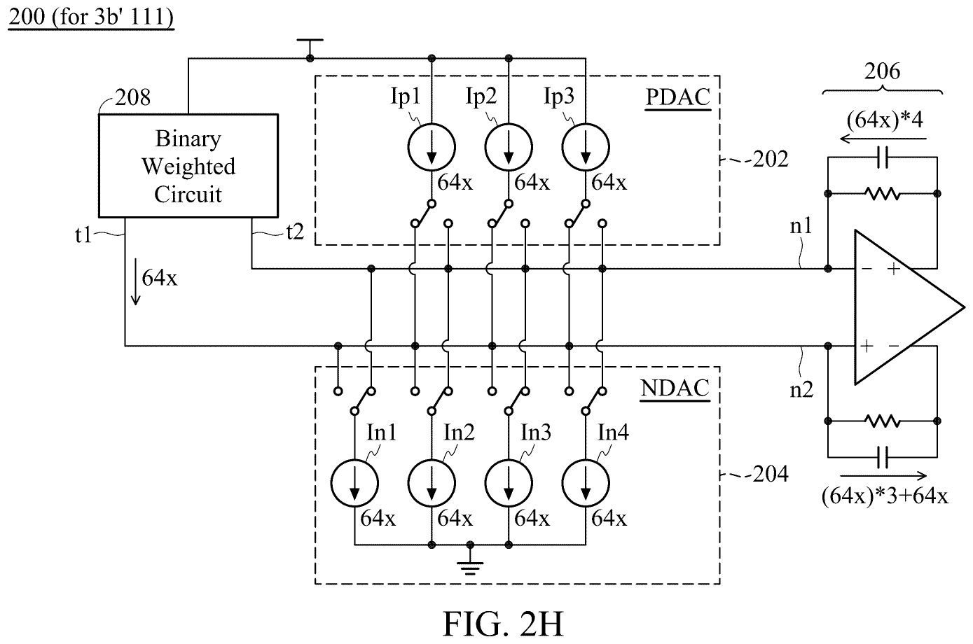

FIGS. 2A to 2H show how a 3-bit DAC 200 works in accordance with an exemplary embodiment of the present invention.

The 3-bit DAC 200 has three (2⁽³⁻¹⁾-1) p-type current sources Ip1, Ip2 and Ip3 in the PDAC 202, and has four (2⁽³⁻¹⁾) n-type current sources In1, In2, In3, and In4 in the NDAC 204. Switches are provided within the PDAC 202 and NDAC 204 to determine how to connect the p-type current sources Ip1˜Ip3 and the n-type current sources In1˜In4 to the first input terminal n1 or the second input terminal n2 of the TIA 206 according to the digital input IN of the 3-bit DAC 200. By controlling the PDAC 202 and NDAC 204 to change the bias current coupled to the TIA 206 according to the digital input IN, an analog signal depending on the digital input IN is generated as the voltage difference at the output port of the TIA 206. The 3-bit DAC 200 further has a binary weighted circuit 208, which has a first output terminal t1 coupled to the second input terminal n2 of the TIA 206, and a second output terminal t2 coupled to the first input terminal n1 of the TIA 206. The binary weighted circuit 208 uses the first output terminal t1 to output a fixed current (64x, multiple of a base current 1x) as an adjustment current. In this example, the p-type current sources in the PDAC 202 each output a current of the fixed value (64x), and the n-type current sources in the NDAC 204 each output a current of the fixed value (64x).

In FIG. 2A, the digital input IN is 3b′ 000. The p-type current sources Ip1˜Ip3 are all connected to the first input terminal n1 of the TIA 206, and the n-type current sources In1˜In4 are all connected to the second input terminal n2 of the TIA 206. The current from the first input terminal n1 to the output port of the TIA 206 is (64x)*3. The current from the output port of the TIA 206 to the second input terminal n2 is (64x)*4-64x.

In FIG. 2B, the digital input IN is 3b′ 001. The p-type current sources Ip1˜Ip3 are all connected to the first input terminal n1 of the TIA 206, the n-type current source In1 is connected to the first input terminal n1 of the TIA 206, and the n-type current sources In2˜In4 are connected to the second input terminal n2 of the TIA 206. The current from the first input terminal n1 to the output port of the TIA 206 is (64x)*2. The current from the output port of the TIA 206 to the second input terminal n2 is (64x)*3-64x.

In FIG. 2C, the digital input IN is 3b′ 010. The p-type current sources Ip1˜Ip3 are all connected to the first input terminal n1 of the TIA 206, the n-type current sources In1 and In2 are connected to the first input terminal n1 of the TIA 206, and the n-type current sources In3 and In4 are connected to the second input terminal n2 of the TIA 206. The current from the first input terminal n1 to the output port of the TIA 206 is (64x)*1. The current from the output port of the TIA 206 to the second input terminal n2 is (64x)*2 64x.

In FIG. 2D, the digital input IN is 3b′ 011. The p-type current source Ip1 is connected to the second input terminal n2 of the TIA 206, the p-type current sources Ip2 and Ip3 are connected to the first input terminal n1 of the TIA 206, the n-type current sources In1 and In2 are connected to the first input terminal n1 of the TIA 206, and the n-type current sources In3 and In4 are connected to the second input terminal n2 of the TIA 206. The current from the first input terminal n1 to the output port of the TIA 206 is (64x)*0. The current from the output port of the TIA 206 to the second input terminal n2 is (64x)*1-64x.

In FIG. 2E, the digital input IN is 3b′ 100. The p-type current sources Ip1 and Ip2 are connected to the second input terminal n2 of the TIA 206, the p-type current source Ip3 is connected to the first input terminal n1 of the TIA 206, the n-type current sources In1 and In2 are connected to the first input terminal n1 of the TIA 206, and the n-type current sources In3 and In4 are connected to the second input terminal n2 of the TIA 206. The current direction is changed in comparison with FIGS. 2A˜2D. The current from the output port of the TIA 206 to the first input terminal n1 is (64x)*1. The current from the second input terminal n2 to the output port of the TIA 206 to is (64x)*0+64x.

In FIG. 2F, the digital input IN is 3b′ 101. The p-type current sources Ip1˜ Ip3 are all connected to the second input terminal n2 of the TIA 206, the n-type current sources In1 and In2 are connected to the first input terminal n1 of the TIA 206, and the n-type current sources In3 and In4 are connected to the second input terminal n2 of the TIA 206. The current from the output port of the TIA 206 to the first input terminal n1 is (64x)*2. The current from the second input terminal n2 to the output port of the TIA 206 to is (64x)*1+64x.

In FIG. 2G, the digital input IN is 3b′ 110. The p-type current sources Ip1˜ Ip3 are all connected to the second input terminal n2 of the TIA 206, the n-type current sources In1˜In3 are connected to the first input terminal n1 of the TIA 206, and the n-type current source In4 is connected to the second input terminal n2 of the TIA 206. The current from the output port of the TIA 206 to the first input terminal n1 is (64x)*3. The current from the second input terminal n2 to the output port of the TIA 206 to is (64x)*2+64x.

In FIG. 2H, the digital input IN is 3b′ 111. The p-type current sources Ip1˜ Ip3 are all connected to the second input terminal n2 of the TIA 206, and the n-type current sources In1˜In4 are all connected to the first input terminal n1 of the TIA 206. The current from the output port of the TIA 206 to the first input terminal n1 is (64x)*4. The current from the second input terminal n2 to the output port of the TIA 206 to is (64x)*3+64x.

The control principles of the p-type current sources Ip1˜Ip3 and the n-type current sources In1˜In4 can be summarized in the following.

Referring to FIGS. 2A˜2C, in response to the digital input IN changing from a first value (3b′ 000 of FIG. 2A) to a second value (3b′ 001 of FIG. 2B, or 3b′ 010 of FIG. 2C) that is greater than the first value (3b′ 000), one or more n-type current sources connected to the second input terminal n2 of the TIA 206 are switched so that they are connected to the first input terminal n1 of the TIA 206. For example, when being changed from FIG. 2A to FIG. 2B, only the connection of In1 is changed. When being changed from FIG. 2A to FIG. 2C, both In1 and In2 are changed in their connections. The connection change from FIG. 2B to FIG. 2C, or from FIG. 2F to FIG. 2G, or from FIG. 2F to FIG. 2H, or from FIG. 2G to FIG. 2H follow the same principle. In these examples, the connection of the p-type current sources Ip1˜Ip3 are kept.

Referring to FIGS. 2C˜2F, in response to the digital input IN changing from a third value (3b′ 010 of FIG. 2C) to a fourth value (3b′ 011 of FIG. 2D, or 3b′ 100 of FIG. 2E, or 3b′ 101 of FIG. 2F) that is greater than the third value (3b′ 010), one or more p-type current sources connected to the first input terminal n1 of the TIA 206 are switched so that they are connected to the second input terminal n2 of the TIA 206. For example, when being changed from FIG. 2C to FIG. 2D, only the connection of Ip1 is changed. When being changed from FIG. 2C to FIG. 2E, both Ip1 and Ip2 are changed in their connections. When being changed from FIG. 2C to FIG. 2F, Ip1˜Ip3 are all changed in their connections. The connection change from FIG. 2D to FIG. 2E, or from FIG. 2D to FIG. 2F, or from FIG. 2E to FIG. 2F follow the same principle.

Referring to FIGS. 2A, 2G, and 2H, in response to the digital input IN changing from a fifth value (3b′ 000 of FIG. 2A) to a sixth value (3b′ 110 of FIG. 2G, or 3b′ 111 of FIG. 2H) that is greater than the fifth value (3b′ 000), one or more p-type current sources connected to the first input terminal n1 of the TIA 206 are switched so that they are connected to the second input terminal n2 of the TIA 206, and one or more of the n-type current sources connected to the second input terminal n2 of the TIA 206 are switched so that they are connected to the first input terminal n1 of the TIA 206. For example, when being changed from FIG. 2A to FIG. 2G, the connections of Ip1˜Ip3 and In1˜In3 are changed. When being changed from FIG. 2A to FIG. 2H, the connections of Ip1˜Ip3 and In1˜In4 are all changed.

In another perspective, the control principles of the p-type current sources Ip1˜Ip3 and the n-type current sources In1˜In4 are summarized in the following.

In response to the digital input IN changing from the second value (3b′ 010 of FIG. 2C) to the seventh value (3b′ 011 of FIG. 2D, or 3b′ 100 of FIG. 2E, or 3b′ 101 of FIG. 2F) that is greater than the second value (3b′ 010), one or more of the p-type current sources connected to the first input terminal n1 of the TIA 206 are switched so that they are connected to the second input terminal n2 of the TIA 206, and the connection of the n-type current sources In1˜In4 are kept.

In response to the digital input IN changing from the seventh value (3b′ 011 of FIG. 2D) to an eighth value (3b′ 100 of FIG. 2E, or 3b′ 101 of FIG. 2F) that is greater than the seventh value 3b′ 011, one or more of the p-type current sources connected to the first input terminal n1 of the TIA 206 are switched so that they are connected to the second input terminal n2 of the TIA 206, and the connection of the n-type current sources In1˜In4 are kept. In response to the digital input IN changing from the eighth value (3b′ 101 of FIG. 2F) to a ninth value (3b′ 110 of FIG. 2G, or 3b′ 111 of FIG. 2H) that is greater than the eighth value (3b′ 101), one or more of the n-type current sources connected to the second input terminal n2 of the TIA 206 are switched so that they are connected to the first input terminal n1 of the TIA 206, and the connection of the p-type current sources Ip1˜Ip3 are kept.

In response to the digital input IN changing from the ninth value (3b′ 110 of FIG. 2G) to a tenth value (3b′ 111 of FIG. 2H) that is greater than the ninth value (3b′ 110), one or more of the n-type current sources connected to the second input terminal n2 of the TIA 206 are switched so that they are connected to the first input terminal n1 of the TIA 206, and the connection of the p-type current sources Ip1˜Ip3 are kept.

To summarize, the control concept of the 3-bit DAC 200 is described in this paragraph. In response to the digital input IN, the current flowing between the first input terminal n1 and the output port of the TIA 206, and the current flowing between the second input terminal n2 and the output port of the TIA 206 depend on the digital input IN, so that the analog signal representing the digital input IN is generated as the voltage difference at the output port of the TIA 206.

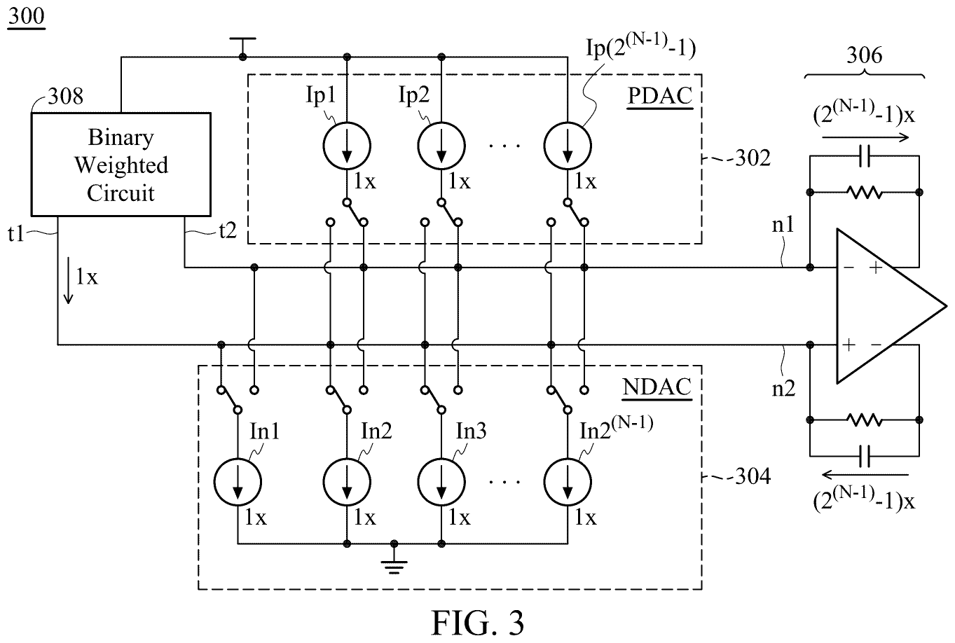

The digital input IN is not limited to a 3-bit signal. FIG. 3 shows an N-bit DAC 300 in accordance with an exemplary embodiment of the present invention, which has a PDAC 302, an NDAC 304, a TIA 306, and a binary weighted circuit 308. In the PDAC 302, the number of p-type current sources is 2^{(N-1)}-1 (referring to Ip1˜Ip(2^{(N-1)}-1)). In the NDAC 304, the number of n-type current sources is 2^{(N-1)} (referring to In1˜In2^{(N-1)}). Each current source provides a current of a fixed value, 1x. The binary weighted circuit 308 outputs an adjustment current (1x) to the second input terminal n2 of the TIA.

In response to the digital input IN being N bits of 0, the 2^{(N-1)}-1 p-type current sources Ip1˜Ip(2^{(N-1)}-1) are all connected to the first input terminal n1 of the TIA 306, and the 2^{(N-1)} n-type current sources In1˜In2^{(N-1)} are all connected to the second input terminal n2 of the TIA 306. The current from the first input terminal n1 to the output port of the TIA 306 is (2^{(N-1)}-1)*1x. The current from the output port of the TIA 306 to the second input terminal n2 is (2^{(N-1)}-1)*1x.

From 1 to 2^{(N-2)}, the greater the digital input IN is, the more n-type current sources are connected to the first input terminal n1 of the TIA 306, wherein the 2^{(N-1)}-1 p-type current sources Ip1˜Ip(2^{(N-1)}-1) are kept connected to the first input terminal n1 of the TIA 306.

From 2^{(N-2)}+1 to 2^{(N-2)}+2^{(N-1)}-1, the greater the digital input IN is, the more p-type current sources are connected to the second input terminal n2 of the TIA 306. There are 2^{(N-2)} n-type current sources kept connected to the first input terminal n1 while the other 2^{(N-2)} n-type current sources kept connected to the second input terminal n2 of the TIA 306.

From 2^{(N-2)}+2^{(N-1)} to 2^{N-1}, the greater the digital input IN is, the more n-type current sources are connected to the first input terminal n1 of the TIA 306, wherein the 2^{(N-1)}-1 p-type current sources Ip1˜Ip(2^{(N-1)}-1) are kept connected to the second input terminal n2 of the TIA 306.

In response to the digital input IN being N bits of 1, the 2^{(N-1)}-1 p-type current sources Ip1˜Ip(2^{(N-1)}-1) are all connected to the second input terminal n2 of the TIA 306, and the 2^{(N-1)} n-type current sources In1˜In2^{(N-1)} are all connected to the first input terminal n1 of the TIA 306.

In some exemplary embodiments, the number of p-type current sources in the PDAC and the number of n-type current sources in the NDAC are not limited. The size each p-type or n-type current source is also not limited. The adjustment current the binary weighted circuit provides to the second input terminal n2 is not limited. Or, in some exemplary embodiments, the binary weighted circuit is provided to sink current from the second input terminal n2 of the TIA rather than to output current to the second input terminal n2 of the TIA. In some exemplary embodiments, the binary weighted circuit also drains/sinks current to the first input terminal n1 of the TIA.

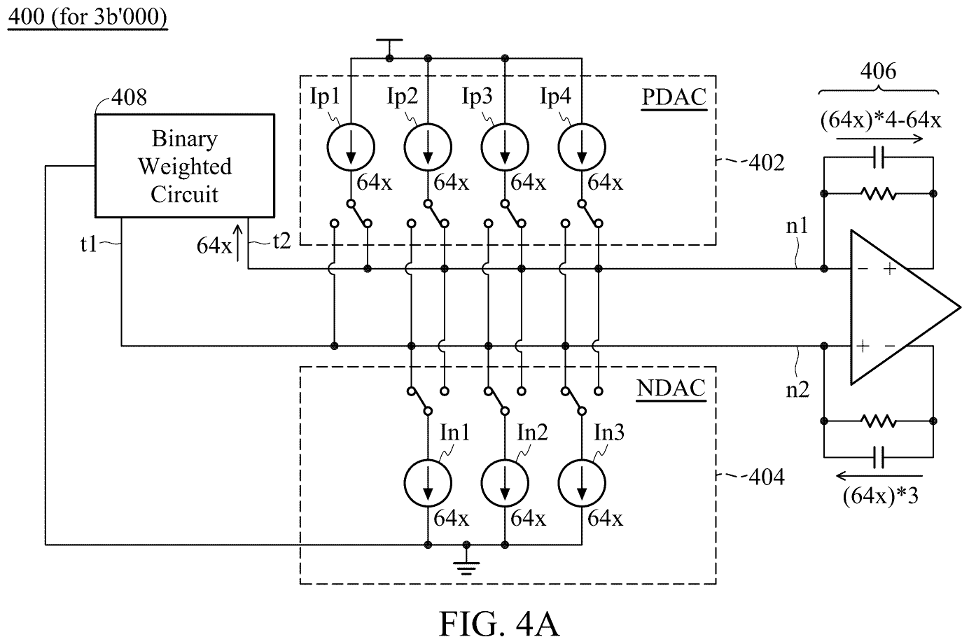

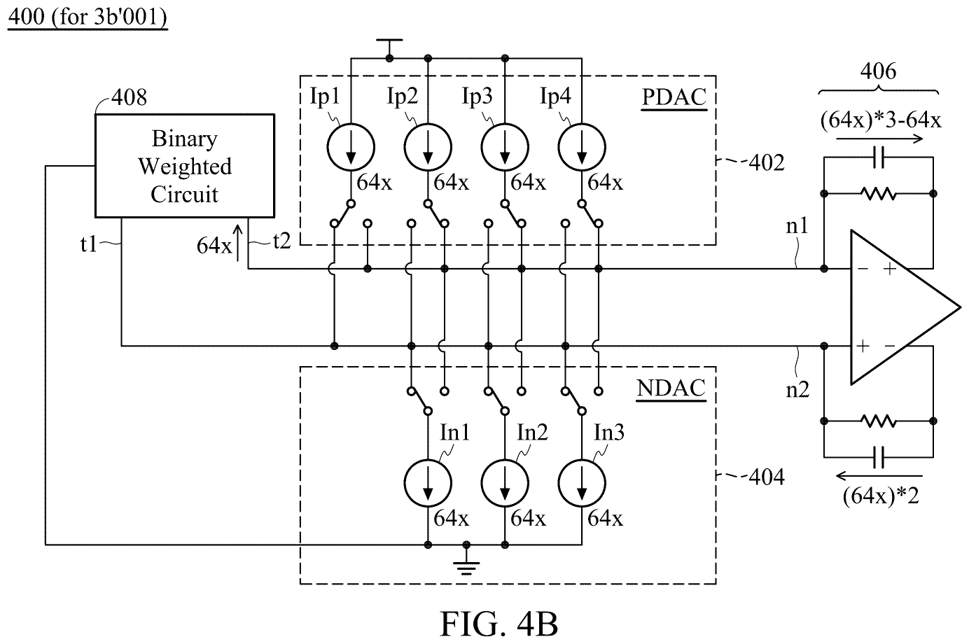

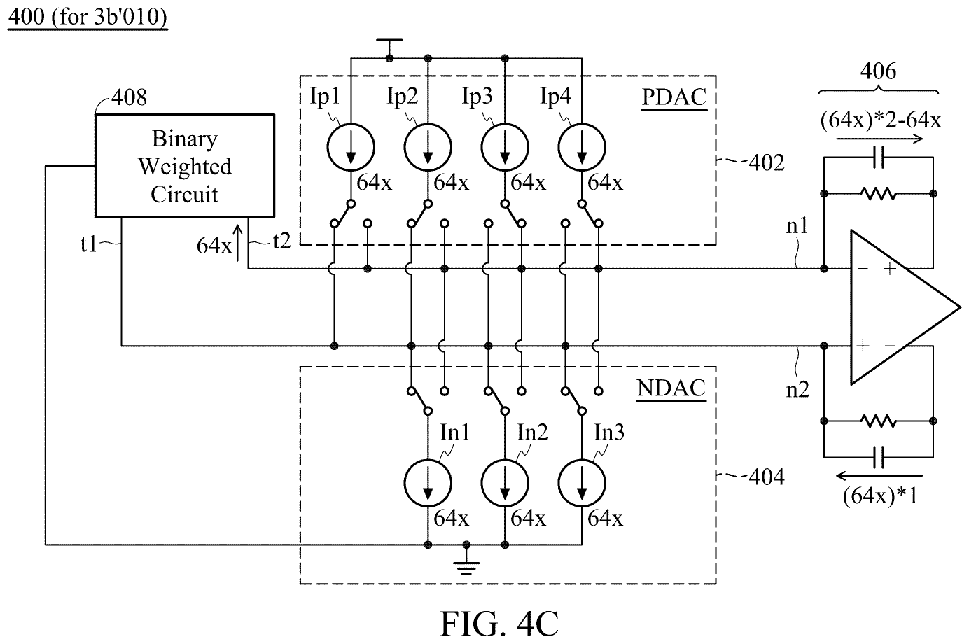

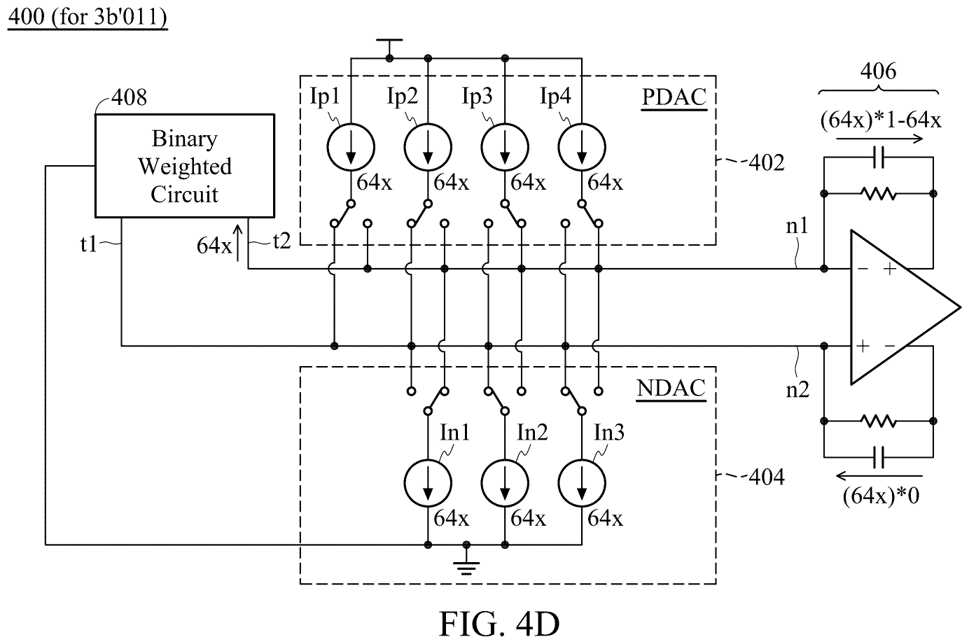

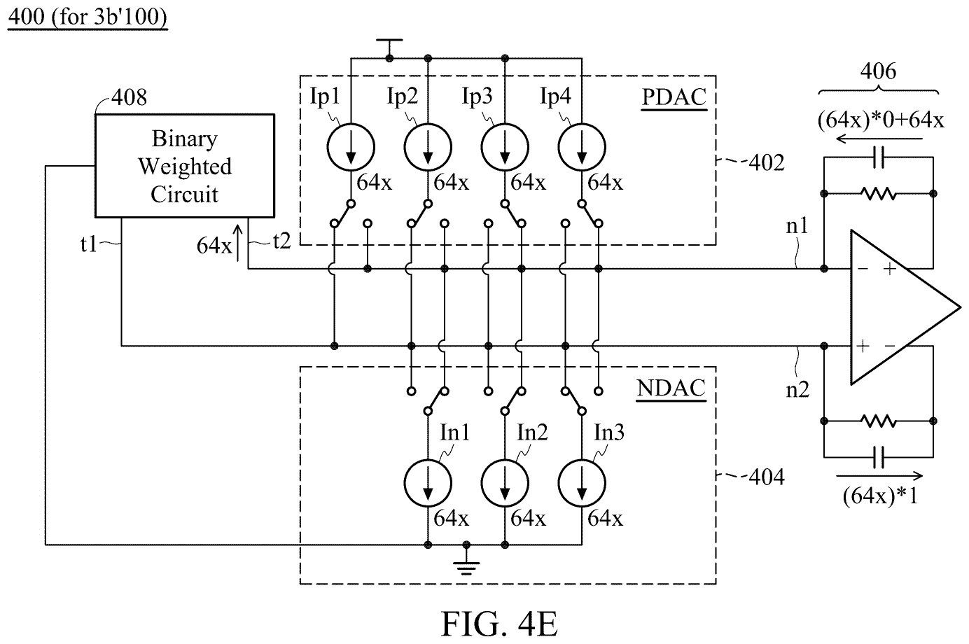

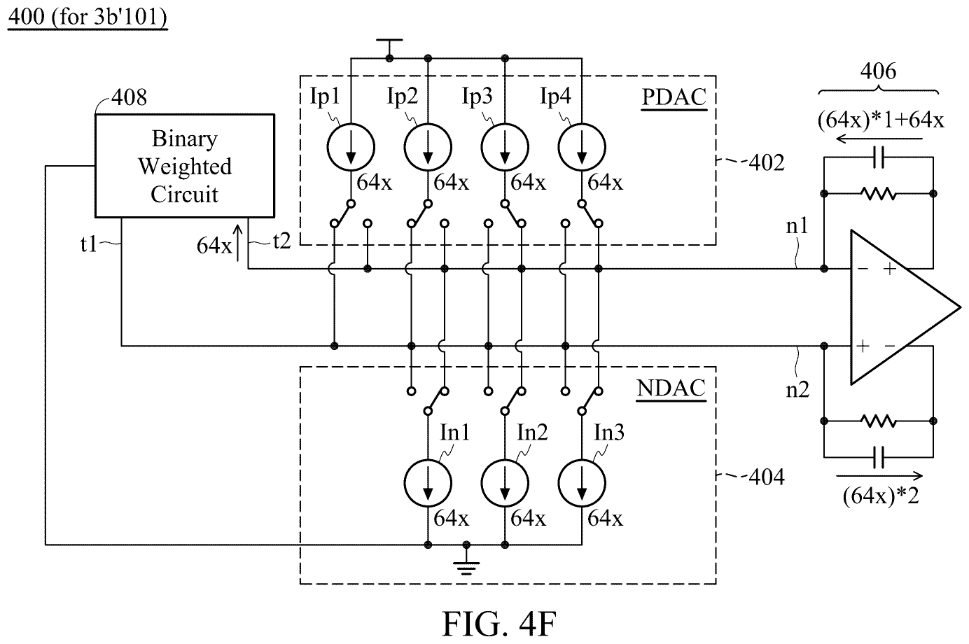

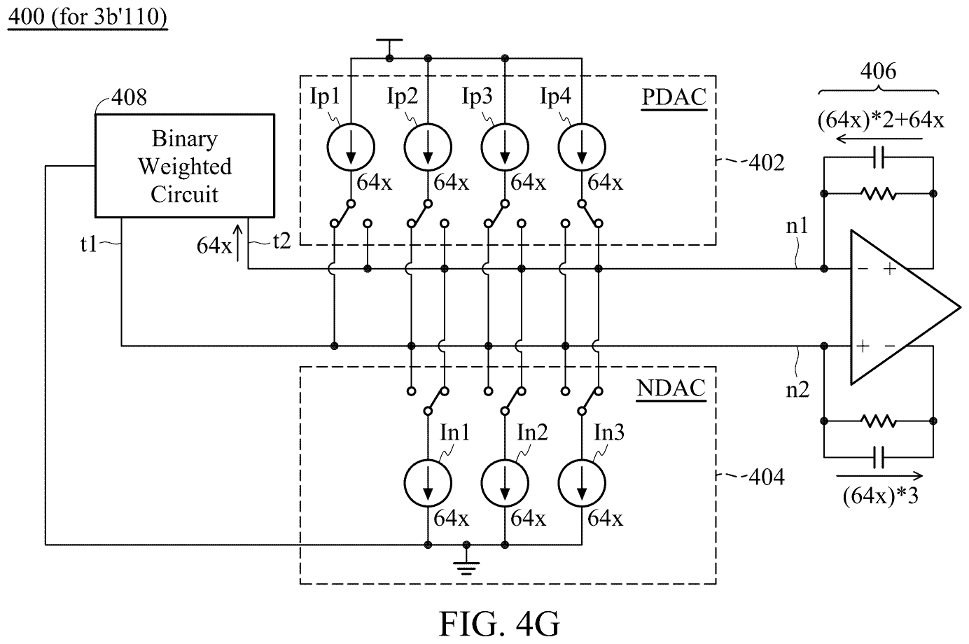

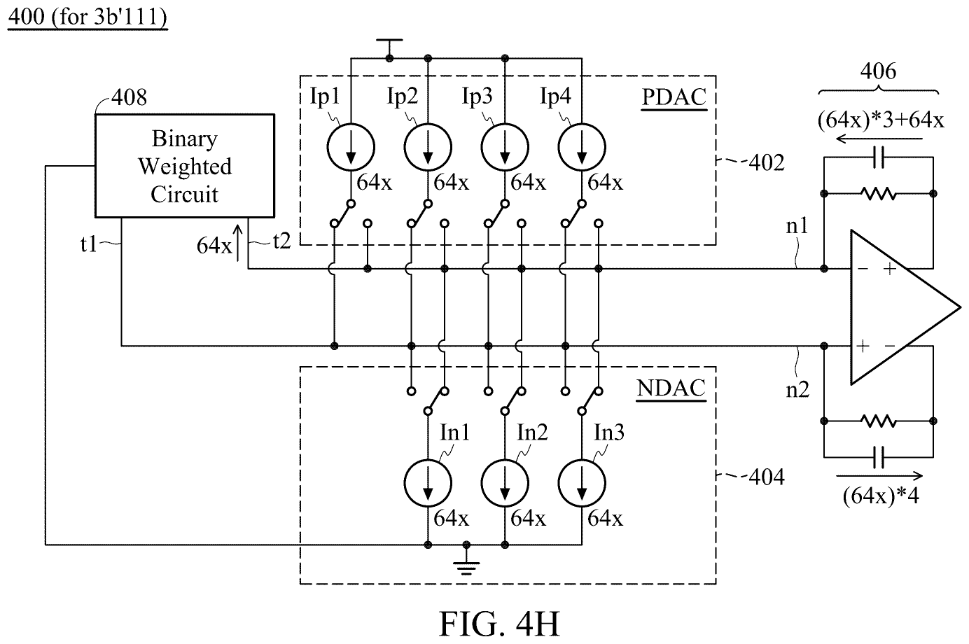

FIGS. 4A˜4H show how a 3-bit DAC 400 works in accordance with another exemplary embodiment of the present invention.

The 3-bit DAC 400 has four (2⁽³⁻¹⁾) p-type current sources Ip1, Ip2, Ip3, and Ip4 in the PDAC 402, and has three (2⁽³⁻¹⁾-1) n-type current sources In1, In2 and In3 in the NDAC 404. Switches are provided within the PDAC 402 and NDAC 404 to determine how to connect the p-type current sources Ip1˜Ip4 and the n-type current sources In1˜In3 to the first input terminal n1 or the second input terminal n2 of the TIA 406 according to the digital input IN of the 3-bit DAC 400. By controlling the PDAC 402 and NDAC 404 to change the bias current coupled to the TIA 406 according to the digital input IN, an analog signal depending on the digital input IN is generated as the voltage difference at the output port of the TIA 406. The 3-bit DAC 400 further has a binary weighted circuit 408, which has a first output terminal t1 coupled to the second input terminal n2 of the TIA 406, and a second output terminal t2 coupled to the first input terminal n1 of the TIA 406. The binary weighted circuit 408 uses the second output terminal t2 to sink a fixed current (64x, multiple of a base current 1x) as an adjustment current. In this example, the p-type current sources Ip1˜Ip4 each output a current of the fixed value (64x), and the n-type current sources In1˜In3 each output a current of the fixed value (64x).

In FIG. 4A, the digital input IN is 3b′ 000. The p-type current sources Ip1˜Ip4 are all connected to the first input terminal n1 of the TIA 406, and the n-type current sources In1˜In3 are all connected to the second input terminal n2 of the TIA 406. The current from the first input terminal n1 to the output port of the TIA 406 is (64x)*4-64x. The current from the output port of the TIA 406 to the second input terminal n2 is (64x)*3.

In FIG. 4B, the digital input IN is 3b′ 001. The p-type current source Ip1 is connected to the second input terminal n2 of the TIA 406, and the p-type current sources Ip2˜Ip4 are connected to the first input terminal n1 of the TIA 406. The n-type current sources In1˜In3 are all connected to the second input terminal n2 of the TIA 406. The current from the first input terminal n1 to the output port of the TIA 406 is (64x)*3-64x. The current from the output port of the TIA 406 to the second input terminal n2 is (64x)*2.

In FIG. 4C, the digital input IN is 3b′ 010. The p-type current sources Ip1 and Ip2 are connected to the second input terminal n2 of the TIA 406, and the p-type current sources Ip3 and Ip4 are connected to the first input terminal n1 of the TIA 406. The n-type current sources In1˜In3 are all connected to the second input terminal n2 of the TIA 406, The current from the first input terminal n1 to the output port of the TIA 406 is (64x)*2-64x. The current from the output port of the TIA 406 to the second input terminal n2 is (64x)*1.

In FIG. 4D, the digital input IN is 3b′ 011. The p-type current sources Ip1 and Ip2 are connected to the second input terminal n2 of the TIA 406, and the p-type current sources Ip3 and Ip4 are connected to the first input terminal n1 of the TIA 406. The n-type current source In1 is connected to the first input terminal n1 of the TIA 406, the n-type current sources In2 and In3 are connected to the second input terminal n2 of the TIA 406. The current from the first input terminal n1 to the output port of the TIA 406 is (64x)*1-64x. The current from the output port of the TIA 406 to the second input terminal n2 is (64x)*0.

In FIG. 4E, the digital input IN is 3b′ 100. The p-type current sources Ip1 and Ip2 are connected to the second input terminal n2 of the TIA 406, and the p-type current sources Ip3 and Ip4 are connected to the first input terminal n1 of the TIA 406. The n-type current sources In1 and In2 are connected to the first input terminal n1 of the TIA 406, the n-type current source In3 is connected to the second input terminal n2 of the TIA 406, The current direction is changed in comparison with FIGS. 4A˜4D. The current from the output port of the TIA 406 to the first input terminal n1 is (64x)*0+64x. The current from the second input terminal n2 to the output port of the TIA 406 to is (64x)*1.

In FIG. 4F, the digital input IN is 3b′ 101. The p-type current sources Ip1 and Ip2 are connected to the second input terminal n2 of the TIA 406, and the p-type current sources Ip3 and Ip4 are connected to the first input terminal n1 of the TIA 406. The n-type current sources In1˜ In3 are all connected to the first input terminal n1 of the TIA 406, The current from the output port of the TIA 406 to the first input terminal n1 is (64x)*1+64x. The current from the second input terminal n2 to the output port of the TIA 406 to is (64x)*2.

In FIG. 4G, the digital input IN is 3b′ 110. The p-type current sources Ip1˜Ip3 are connected to the second input terminal n2 of the TIA 406, and the p-type current source Ip4 is connected to the first input terminal n1 of the TIA 406. The n-type current sources In1˜ In3 are all connected to the first input terminal n1 of the TIA 406, The current from the output port of the TIA 406 to the first input terminal n1 is (64x)*2+64x. The current from the second input terminal n2 to the output port of the TIA 406 to is (64x)*3.

In FIG. 4H, the digital input IN is 3b′ 111. The p-type current sources Ip1˜Ip4 are all connected to the second input terminal n2 of the TIA 406. The n-type current sources In1˜ In3 are all connected to the first input terminal n1 of the TIA 406. The current from the output port of the TIA 406 to the first input terminal n1 is (64x)*3+64x. The current from the second input terminal n2 to the output port of the TIA 406 to is (64x)*4.

In response to the digital input IN, the current flowing between the first input terminal n1 and the output port of the TIA 406, and the current flowing between the second input terminal n2 and the output port of the TIA 406 depend on the digital input IN, so that the analog signal representing the digital input IN is generated as the voltage difference at the output port of the TIA 406.

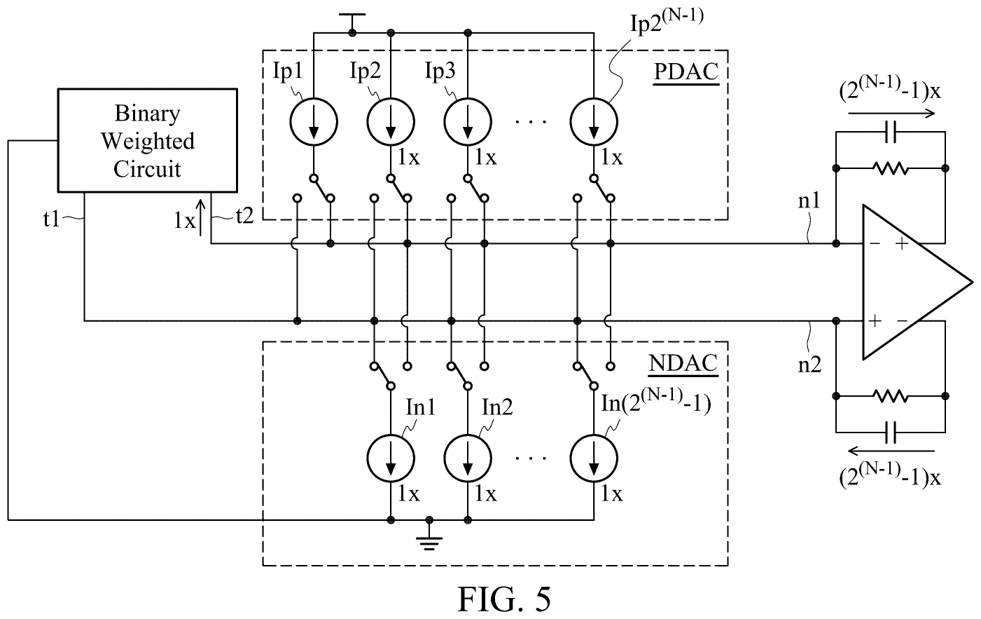

Compared with the example of FIGS. 2A˜2H which has less p-type current sources and more n-type current sources, the 3-bit DAC introduced in FIGS. 4A˜4H has more p-type current sources and less n-type current sources. The N-bit DAC 300 of FIG. 3 may be modified by the similar concept. FIG. 5 shows an N-bit DAC in accordance with an exemplary embodiment of the present invention, which uses more p-type current sources (e.g., 2^{(N-1)} p-type current sources Ip1˜Ip2^{(N-1)}) and less n-type current sources. (e.g., 2^{(N-1)}-1 n-type current sources In1˜In(2^{(N-1)}-1)). The binary weighted circuit uses the terminal t2 to sink a current 1x from the first input terminal n1 without using the terminal t1.

In response to the digital input IN being N bits of 0, the 2^{(N-1)} p-type current sources Ip1˜Ip2^{(N-1)} are all connected to the first input terminal n1 of the TIA, and the 2^{(N-1)}-1 n-type current sources In1˜In(2^{(N-1)}-1) are all connected to the second input terminal n2 of the TIA. The current from the first input terminal n1 to the output port of the TIA is (2^{(N-1)}-1)*1x. The current from the output port to the second input terminal n2 of the TIA is (2^{(N-1)}-1)*1x.

From 1 to 2^{(N-2)}, the greater the digital input IN is, the more p-type current sources are connected to the second input terminal n2, wherein the 2^{(N-1)}-1 n-type current sources In1˜In(2^{(N-1)}-1) are kept connected to the second input terminal n2 of the TIA.

From 2^{(N-2)}+1 to 2^{(N-2)}+2^{(N-1)}-1, the greater the digital input IN is, the more n-type current sources are connected to the first input terminal n1 of the TIA. There are 2^{(N-2)} p-type current sources kept connected to the second input terminal n2 while the other 2^{(N-2)} p-type current sources kept connected to the first input terminal n1 of the TIA.

From 2^{(N-2)}+2^{(N-1)} to 2^{N-1}, the greater the digital input IN is, the more p-type current sources are connected to the second input terminal n2 of the TIA, wherein the 2^{(N-1)}-1 n-type current sources are kept connected to the first input terminal n1 of the TIA.

In response to the digital input IN being N bits of 1, the 2^{(N-1)} p-type current sources are all connected to the second input terminal n2 of the TIA, and the 2^{(N-1)}-1 n-type current sources are all connected to the first input terminal n1 of the TIA.

In such an example wherein the p-type current sources are more than the n-type current sources, the number of p-type current sources in the PDAC and the number of n-type current sources in the NDAC are also not limited. The size each p-type or n-type current source is not limited. The adjustment current that the binary weighted circuit sinks from the first input terminal n1 of the TIA is not limited. Or, in some exemplary embodiments, the binary weighted circuit is provided to output current to the first input terminal n1 rather than to sink current from the first input terminal n1 of the TIA. In some exemplary embodiments, the binary weighted circuit also drains/sinks current to the second input terminal n2 of the TIA.

In some exemplary embodiments, the number of p-type current sources provided by the PDAC is the same as the number of n-type current sources provided by the NDAC.

The number of p-type current sources is L, and number of n-type current sources is K. L and M are two integers greater than 1. In some exemplary embodiments, L may be greater than K. In some exemplary embodiments, K may be greater than L. In some exemplary embodiments, K=L.

Any current-steering DAC with the aforementioned complementary bias design (PDAC and NDAC) should be considered within the scope of the present invention.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A complementary current-steering digital-to-analog converter, comprising:
a transimpedance amplifier;
a p-type digital-to-analog converter, comprising a plurality of p-type current sources, wherein the p-type current sources are coupled to a first input terminal or a second input terminal of the transimpedance amplifier according to a digital input of the complementary current-steering digital-to-analog converter; and
an n-type digital-to-analog converter, comprising a plurality of n-type current sources, wherein the n-type current sources are coupled to the first input terminal or the second input terminal of the transimpedance amplifier according to the digital input of the complementary current-steering digital-to-analog converter.

2. The complementary current-steering digital-to-analog converter as claimed in claim 1, wherein:
the number of p-type current sources is L, where L is an integer greater than 1;
the number of n-type current sources is K, where K is an integer greater than 1.

3. The complementary current-steering digital-to-analog converter as claimed in claim 1, further comprising:
a binary weighted circuit, configured to sink or output an adjustment current from or to the second input terminal of the transimpedance amplifier.

4. The complementary current-steering digital-to-analog converter as claimed in claim 1, further comprising:
a binary weighted circuit, configured to sink or output an adjustment current from or to the first input terminal of the transimpedance amplifier.

5. The complementary current-steering digital-to-analog converter as claimed in claim 1, further comprising:
a binary weighted circuit, having a first output terminal coupled to the second input terminal of the transimpedance amplifier to sink or output an adjustment current from or to the second input terminal of the transimpedance amplifier, and a second output terminal coupled to the first input terminal of the transimpedance amplifier to sink or output an adjustment current from or to the first input terminal of the transimpedance amplifier.

6. The complementary current-steering digital-to-analog converter as claimed in claim 1, wherein:
the digital input is N bits, wherein N is a number;
the number of p-type current sources is 2^{(N-1)}-1; and
the number of n-type current sources is 2^{(N-1)}.

7. The complementary current-steering digital-to-analog converter as claimed in claim 6, wherein:
in response to the digital input being N bits of 0, the 2^{(N-1)}-1 p-type current sources are connected to the first input terminal of the transimpedance amplifier, and the 2^{(N-1)} n-type current sources are connected to the second input terminal of the transimpedance amplifier; and
in response to the digital input being N bits of 1, the 2^{(N-1)}-1 p-type current sources are connected to the second input terminal of the transimpedance amplifier, and the 2^{(N-1)} n-type current sources are connected to the first input terminal of the transimpedance amplifier.

8. The complementary current-steering digital-to-analog converter as claimed in claim 7, wherein:
from 1 to 2^{(N-2)}, the greater the digital input is, the more n-type current sources are connected to the first input terminal of the transimpedance amplifier, wherein the 2^{(N-1)}-1 p-type current sources are kept connected to the first input terminal of the transimpedance amplifier;
from 2^{(N-2)}+1 to 2^{(N-2)}+2^{(N-1)}-1, the greater the digital input is, the more p-type current sources are connected to the second input terminal of the transimpedance amplifier, and, there are 2^{(N-2)} n-type current sources connected to the first input terminal of the transimpedance amplifier, and 2^{(N-2)} n-type current sources connected to the second input terminal of the transimpedance amplifier; and
from 2^{(N-2)}+2^{(N-1)} to 2^{N}-1, the greater the digital input is, the more n-type current sources are connected to the first input terminal of the transimpedance amplifier, wherein the 2^{(N-1)}-1 p-type current sources are kept connected to the second input terminal of the transimpedance amplifier.

9. The complementary current-steering digital-to-analog converter as claimed in claim 8, wherein:
the p-type current sources each generate a current of a fixed value; and
the n-type current sources each generate a current of the same fixed value.

10. The complementary current-steering digital-to-analog converter as claimed in claim 9, further comprising:
a binary weighted circuit, configured to output an adjustment current of the fixed value to the second input terminal of the transimpedance amplifier.

11. The complementary current-steering digital-to-analog converter as claimed in claim 1, wherein:
the digital input is N bits, wherein N is a number;
the number of p-type current sources is 2^{(N-1)}; and
the number of n-type current sources is 2^{(N-1)}-1.

12. The complementary current-steering digital-to-analog converter as claimed in claim 11, wherein:
in response to the digital input being N bits of 0, the 2^{(N-1)} p-type current sources are connected to the first input terminal of the transimpedance amplifier, and the 2^{(N-1)}-1 n-type current sources are connected to the second input terminal of the transimpedance amplifier; and
in response to the digital input being N bits of 1, the 2^{(N-1)} p-type current sources are connected to the second input terminal of the transimpedance amplifier, and the 2^{(N-1)}-1 n-type current sources are connected to the first input terminal of the transimpedance amplifier.

13. The complementary current-steering digital-to-analog converter as claimed in claim 12, wherein:
from 1 to 2^{(N-2)}, the greater the digital input is, the more p-type current sources are connected to the second input terminal of the transimpedance amplifier, wherein the 2^{(N-1)}-1 n-type current sources are kept connected to the second input terminal of the transimpedance amplifier;
from 2^{(N-2)}+1 to 2^{(N-2)}+2^{(N-1)}-1, the greater the digital input is, the more n-type current sources are connected to the first input terminal of the transimpedance amplifier, and, there are 2^{(N-2)} p-type current sources connected to the second input terminal of the transimpedance amplifier, and 2^{(N-2)} p-type current sources connected to the first input terminal of the transimpedance amplifier; and
from 2^{(N-2)}+2^{(N-1)} to 2^{N}-1, the greater the digital input is, the more p-type current sources are connected to the second input terminal of the transimpedance amplifier, wherein the 2^{(N-1)}-1 n-type current sources are kept connected to the first input terminal of the transimpedance amplifier.

14. The complementary current-steering digital-to-analog converter as claimed in claim 13, wherein:
the p-type current sources each generate a current of a fixed value; and
the n-type current sources each generate a current of the same fixed value.

15. The complementary current-steering digital-to-analog converter as claimed in claim 14, further comprising:
a binary weighted circuit, configured to sink an adjustment current of the fixed value from the first input terminal of the transimpedance amplifier.
